(19) United States
(12) Patent Application Publication
(10) Pub. No.: US 2007/0256934 A1
(43) Pub. Date: Nov. 8, 2007

(54) Apparatus and Method for Coating Substrates With Approximate Process Isolation

(76) Inventors: Michael Robert Perata, Suisun City, CA (US); Michael Lee Strahlendorf, Oakley, CA (US)

Correspondence Address: DAVIS WRIGHT TREMAINE LLP, 505 MONTGOMERY STREET, SUITE 800, SAN FRANCISCO, CA, 94111, US

(21) Appl. No.: 11/382,241

(22) Filed: May 8, 2006

(51) Int. Cl. C23C 14/32; C23C 14/00; C23C 16/00

(52) U.S. Cl. 204/298.23; 118/719; 204/192.1

(57) ABSTRACT

Apparatus for coating a substrate may comprise two process compartments that flank a pump compartment. The pump compartment is in operable communication with the two process compartments and a pathway for pumping gas therefrom via pumps, and is sufficient for approximately isolating the gas associated with the one process compartment and the gas associated with the other process compartment relative to one another in association with a substrate coating process. The pump compartment may be so sufficient when the pathway length is less than two times the path length associated with one process compartment, the path length associated with the other process compartment, or the average of the two path lengths. Apparatus for pumping gas associated with a substrate coating process and methods associated with coating a substrate or pumping gas are also provided.

### BACKGROUND

Apparatus and methods of coating substrates are of interest in connection with a variety of useful applications. By way of example, apparatus and methods employing vacuum and various process gases in the coating of large substrates, such as large sheets of glass, for example, have been of interest for some time. Large substrates, such as sheets of architectural glass, may be coated with a variety of materials to modify their optical, thermal, and/or aesthetic qualities. For example, an optical coating may be used to reduce the transmission of visible light, to decrease absorption of energy, to reduce reflectance, and/or to pursue any combination of qualities. Such an optical coating may be referred to as a solar control coating, a low emissivity coating, an anti-reflective coating, and/or a multipurpose coating, respectively. U.S. Pat. No. 6,589,657, entitled “Anti-reflection Coatings and Associated Methods,” and U.S. Published Patent Application No. 2003/0043464, entitled “Optical Coatings and Associated Methods,” each of which is incorporated herein in its entirety by this reference, describe the formation and use of coatings that affect the optical characteristics of a glass substrate.

A coating system generally includes a coater and some connected, remote units. The coater (which may also be called a coating system) generally comprises multiple process modules, or chambers, arranged in series so that a substrate or substrates can pass from one process module to the next. The substrate is generally supported and moved through the coater along a substrate passline in an upstream-to-downstream direction by rollers. The substrate generally enters the coater at one end, or upstream end, passes through multiple process modules where it is coated with a material or different materials, and exits the coater at another end, or downstream end. The substrate may be oriented so that it is horizontal or nearly so and is moved along a horizontal or nearly horizontal plane through the coater, may be oriented so that it is vertical or nearly so and is moved along a vertical or nearly vertical plane through the coater, or may be otherwise oriented and moved accordingly through the coater.

The coating of large substrates can be challenging. By way of example, architectural glass is generally produced in large sheets measuring up to 3.2 meters by 6 meters (126 inches by 236 inches), which may be difficult to handle and process in a coating system. A coating system suitable for coating large substrates, such as architectural glass, for example, may be several hundred feet long in the direction of the substrate passline, may occupy a significant amount of area in a processing facility, and may be quite expensive to purchase, house, operate and maintain.

FIG. 1 is a schematic illustration of a coater 2 that may be used to coat a substrate 4, such as to coat a large substrate as just described, for example, or several such substrates. The illustration shows the coater 2 from an elevated view of the top, a side, and a downstream end of the coater, with a substrate 4 exiting from the downstream end of the coater. The coater 2 may have a number of process modules, such as process modules A and B, arranged in series as shown, through which the substrate 4 passes in an upstream-to-downstream direction (as schematically indicated by the directional arrow) during processing. In this example, the substrate 4 has a horizontal orientation for traveling along a horizontal plane through the process modules of the coater 2, as shown. The coater 2 may have a number of slit valves located between process modules, which may be located in chambers, such as the slit valve chambers 6, 8 and 10 shown in FIG. 1.

FIG. 2 provides a more detailed schematic illustration of a portion of such a coater. The illustration shows a coater 2 from an elevated view of the top of the coater, the same side of the coater associated with FIG. 1, and a portion of the coater nearer to the upstream end of the coater that is opposite the downstream end discussed in connection with FIG. 1. In this illustration, the coater 2 is shown from an upstream to a downstream perspective as having a slit valve chamber 6, a process module A that is made up of six compartments 14, or bays, including compartments A5 and A6, a slit valve chamber 8, and a process module B that is made up of several compartments 14, including compartments B1 and B2. The coater 2 may have several rollers 10 to move the substrate or substrates (not shown) along the substrate passline 12, a path along which the substrate or substrates are moved through the coater in an upstream-to-downstream direction (as schematically indicated by arrows associated with the substrate passline). In this illustration, rollers 10 are located in each of the compartments. The rollers 10 may have a width appropriate to support the entire width of the substrate or substrates, such as a width more or less commensurate with the substrate width SW (FIG. 1) from about 1000 mm to about 3300 mm up to a compartment width CW (FIG. 1) from about 1000 mm to about 4210 mm, for example, and a separation distance SD (FIG. 2) parallel to the substrate passline appropriate to support the substrate or substrates, such as a separation distance of not more than about 300 mm, for example. In general, all of the rollers 10 in the coater 2 may be rotated at approximately the same rate and the movement of the substrate or substrates through the coater may be at an approximately constant rate.

The slit valves of slit valve chambers that separate process modules may be open to allow a substrate to pass from one process module to another during processing. A process module may thus be in fluid communication with a neighboring process module via slit valve opening or multiple neighboring processing modules via multiple slit valve openings. This fluid communication may be reduced in various ways. By way of example, the slit valve opening or openings may be restricted in size, to the extent practicable or possible while allowing for passage of the substrate therethrough, for example, to reduce this fluid communication between process modules. Further by way of example, a gap or spacing between substrates passing along the substrate passline may be restricted, to the extent practicable or possible, to reduce the amount of fluid that may be carried in or by the gap along the substrate pass line, and thus the fluid communication between process modules.

Each of the process modules of the coater may be made up of a number of compartments 14. The number of compartments 14 per process module may be the same or different. As such, a dimension of a process module that is parallel to the substrate passline and extends from the entrance to the exit of the process module may be the same as that of another process module (as shown in FIG. 1) or different from that of another process module. By way of convention, a dimension such as this that is parallel to the substrate passline will be referred to herein as a “length,” even if it is not the longest dimension of the subject item. (See the length AL of process module A and length BL of process module B in FIGS. 1 and 2, for example.) The compartments of the process modules may be uniform in size, such as length (about 600 mm to about 1005 mm, for example), width (about 1000 mm to about 4210 mm, for example), depth (about 350 mm to about 1000 mm, for example), and volume (about 0.2 m³ to about 3 m³, for example), for example, as demonstrated by compartments 14 of FIG. 2, as this may facilitate configuration and/or reconfiguration of the process modules, and thus the overall coater. The compartments may be used for similar or different purposes. By way of example, a compartment may be used for a process, such as the coating of a substrate within the process compartment. Further by way of example, a compartment may be used for another purpose or other purposes, such as pumping via one or more pumps operably associated with the pump compartment. Process compartments having different functions, such as deposition or coating compartments and pumping compartments, may be interchangeable.

A coater, such as that shown in either of FIGS. 1 and 2, may be used in a coating process that involves the sputtering of a target material from a cylindrical or planar target onto the substrate as the substrate moves past the target. The sputtering of target material onto large substrates may involve the use of a high power electrical supply appropriate for sputtering and the use of cooling water for appropriate thermal control, such as the avoidance of excessive heating, for example. A system and a method for depositing material via a cylindrical target or magnetron are described in U.S. Pat. No. 6,736,948, entitled “Cylindrical AC/DC Magnetron with Compliant Drive System and Improved Electrical and Thermal Isolation,” which is hereby incorporated by reference in its entirety. A system and a method for depositing material via a planar target or magnetron are described in U.S. Pat. No. 4,166,018, entitled “Sputtering Process and Apparatus,” which is hereby incorporated by reference in its entirety.

Sputtering generally takes place in a vacuum environment. In this context, the term “vacuum” may refer to a gas at any pressure below atmospheric pressure. In general, sputtering processes for coating glass are carried out in the millitorr range. In sputtering processes for coating large sheets of glass, the sheets are moved past the target under vacuum while the target rotates and while the target material is sputtered. The process involves maintaining a vacuum environment appropriate for sputtering while moving parts within that vacuum environment. In some sputtering processes, a gas may be introduced into the sputtering compartment to allow reactive sputtering to take place. In general, reactive sputtering involves interaction or reaction of the gas and the sputtered target material to form a layer on a substrate. The amount of gas that may be introduced in a sputtering process is generally small so that the process pressure remains well below atmospheric pressure and the process compartment may still be considered to be under vacuum.

In the coater 2 of FIG. 2, process compartments having different functions, such as deposition or coating compartments and pumping compartments, may be interchangeable. In this coater, for example, compartments A5 and B2 may be process compartments that are used to deposit material onto a substrate, such as by sputtering, for example, and compartments A6 and B1, which are located between the process compartments A5 and B2, may be pump compartments that are used to provide appropriate vacuum. FIG. 3 is a schematic illustration of a portion of such a coater 2, viewed from a side of the coater, shown in vertical cross-section. As shown, from upstream to downstream, the coater 2 has a pump compartment A6 that is associated with a process module A, a slit valve chamber 8, and a pump compartment B1 that is associated with a process module B. Each of the pump compartments A6 and B1 is equipped with several rollers 10, as previously described, as well as a pump 16 and 18, respectively, located on a top of the pump compartment. Each of the pump compartments A6 and B1 is typically equipped with more than one pump 16 and 18, respectively. Each of the pumps 16 and 18 may be further associated with a backing pump or several backing pumps (not shown).

As mentioned previously, a process module may be in fluid communication with a neighboring process module or multiple neighboring processing modules. As such, gas may flow between neighboring process modules, such as process modules A and B of FIGS. 1-3. In general, it is desirable to reduce, minimize or eliminate this flow of gas between process modules during processing. This is particularly so if the processes associated with the process modules are not sufficiently compatible or are incompatible. While incompatible processes are generally not carried out in the same process module, they may be carried out in adjacent process modules.

Similarly, a process compartment may be in fluid communication with a neighboring process compartment or multiple neighboring processing compartments. As such, gas may flow between neighboring process compartments, such as process modules A5 and A6, A6 and B1, and B1 and B2 of FIG. 2. In general, it is desirable to reduce, minimize or eliminate this flow of gas between process compartments during processing. This is particularly so if the processes associated with the process compartments are not sufficiently compatible or are incompatible. While incompatible processes are generally not carried out in adjacent process compartments, they may be carried out in process compartments that are separated by pump compartments. By way of example, a process compartment that is used for a reactive sputtering process that uses an oxygen environment to produce an oxide layer may be located upstream or downstream relative to a process compartment that is used for a process that is sensitive to oxygen presence or oxygen contamination. In such a case, or any other appropriate case, pump compartments, and associated pumps, respectively, may be located in between the two process compartments, and may be employed on one side and another side, respectively, of a slit valve chamber, or side by side, to reduce gas flow or contamination between the two process compartments. In this way, a gas or a contaminant associated with a process in one process compartment, or a sufficient amount of same, is likely to be pumped out of the coater before it reaches the slit valve chamber or the adjacent process compartment.

By way of illustration, when process compartment A5 and pump compartment A6 are configured in process module A, pump compartment B1 and process compartment B2 are configured in process module B, and process module A and process module B are located on opposite sides of slit valve chamber 8, as shown in FIG. 2, the pump 16 associated with pump compartment A6, as shown in FIG. 3, may be used to reduce the amount of gas from pump compartment A6 that reaches or diffuses to slit valve chamber 8, and the pump 18 associated with pump compartment B1, as shown in FIG. 3, may be used to reduce the amount of gas from pump compartment B1 that reaches or diffuses to process compartment B2. The pump compartments A6 and B1 and associated pumps 16 and 18, respectively, may thus be used to reduce the flow of gas from process compartment A5 to process compartment B2, or to provide some level of gas isolation between these process compartments. Systems and methods such as the foregoing, which employ a configuration of at least two pump compartments, associated pumps, and a slit valve chamber, have been used to provide some level of gas isolation, between neighboring process compartments and/or modules.

Development of apparatus, systems and methods for coating substrates is generally desirable.

### SUMMARY

An apparatus for coating a substrate passing therethrough is provided. The apparatus may comprise a process compartment that is sufficient for passage of the substrate therethrough via a path and for coating the substrate via a gas, another process compartment of similar characteristics, and a pump compartment disposed between the two process compartments. For each process compartment, the length of the path may extend from an entrance to an exit of the process compartment. The gas used in the two process compartments may be the same or different. The pump compartment is sufficient for passage of a substrate therethrough via a pathway of a length that extends from an entrance to an exit of the pump compartment. The pathway is in operable communication with the paths associated with the two pump compartments.

In the apparatus just described, the pump compartment is in operable communication with the two process compartments and the pathway for pumping gas therefrom via pumps. The pump compartment is sufficient for approximately isolating the gas associated with one process compartment and the gas associated with the other process compartment relative to one another in association with a substrate coating process. The pump compartment may be so sufficient when the pathway length is less than two times the path length associated with one process compartment, the path length associated with the other process compartment, or the average of the two path lengths. The apparatus may be sufficient to provide a ratio of a pressure of the gas associated with the one process compartment and a pressure of the gas associated with the other process compartment of up to about 35 to 1 in association with the substrate coating process.

A method of pumping gas from an apparatus for coating a substrate passing therethrough is also provided. The method may comprise providing the apparatus just described and pumping gas from the pathway and the two process compartments via the pumps in association with the substrate coating process. The pumping may be sufficient for approximately isolating the gas associated with one process compartment and the gas associated with the other process compartment relative to one another in association with a substrate coating process.

An apparatus for pumping gas associated with a substrate coating process is also provided. The apparatus may comprise a pump compartment and high vacuum pumps. The pump compartment is adapted for operable communication with a process compartment adjacent one side of the pump compartment and another process compartment adjacent another side of the pump compartment. The process compartment on the one side is of one length and the process compartment on the other side is of another length. The pump compartment has a pathway for passage of a substrate through the pump compartment. The pathway length is less than two times the length associated with one process compartment, the length associated with the other process compartment, or an average of these two lengths. The high vacuum pumps are operably associated with the pump compartment and are sufficient for approximately isolating a gas associated with one process compartment and a gas associated with the other process compartment relative to one another in association with the substrate coating process. These gases may be the same or different.

A method of pumping gas associated with a substrate coating process is also provided. The method may comprise providing the apparatus just described and pumping gas from the pathway, one process compartment, and the other process compartment via the pumps in association with the substrate coating process. The pumping may be sufficient for approximately isolating the gas associated with one process compartment and the gas associated with the other process compartment relative to one another in association with a substrate coating process.

A single pump compartment may be sufficient to provide an acceptable level of gas isolation, where desirable or needed, between process or coat compartments. It is contemplated that when used in a coater, such a single pump compartment may correspond to a gas isolation ratio of more than about 20 to one, such as up to about 35 to one, for example. Use of a single pump compartment may be advantageous in terms of reductions in equipment costs, coater footprint, configuration time and effort, operational time and effort, and coater complexity, and/or the like, and particularly advantageous in the context of large, multi-module coaters, such as those employed to coat a substrate with five or more layers of material, such as six to eight layers of material, for example, which have heretofore employed a significant number of gas isolation compartments. It is contemplated that a variety of multi-module coaters that comprise a configuration of three compartments or bays, in which a single pump compartment is flanked by two coat compartments, such as those described herein, for example, may be useful.

These and various other aspects, features, and embodiments are further described herein.

### BRIEF DESCRIPTION OF THE DRAWINGS

A description of various aspects, features and embodiments is provided herein with reference to the accompanying drawings, which are briefly described below. The drawings are illustrative and are not necessarily drawn to scale. The drawings illustrate various background material or various aspects or features and may illustrate one or more embodiment(s) or example(s) in whole or in part. A reference numeral, letter, and/or symbol that is used in one drawing to refer to a particular element or feature may be used in another drawing to refer to a like element or feature.

FIG. 1 (FIG. 1) is a schematic illustration of a modular coater from a viewpoint as described herein.

FIG. 2 (FIG. 2) is a schematic illustration of a cut-away portion of a modular coater, some internal features of which have been rendered visible for illustration purposes, from a viewpoint as described herein.

FIG. 3 (FIG. 3) is a schematic illustration of a cut-away portion of a modular coater, shown in vertical cross-section, as viewed from a side of the coater.

FIG. 4A (FIG. 4A) is a schematic illustration of a portion of a modular coater, as viewed from a top of the coater. FIG. 4B (FIG. 4B) is a schematic illustration of a portion of a modular coater, shown in vertical cross-section, as viewed from a side of the coater. FIG. 4A and FIG. 4B may be collectively referred to as FIG. 4 herein.

FIG. 5A (FIG. 5A) is a schematic illustration of a structure of a modular, compartment-type coater from a viewpoint as described herein. FIG. 5B (FIG. 5A) is a schematic illustration of a cut-away portion of a modular coater, shown in horizontal cross-section, as viewed from a top of the coater. FIG. 5C (FIG. 5C) is a schematic illustration of a cut-away portion of a modular coater, shown in vertical cross-section, as viewed from a side of the coater. FIG. 5A, FIG. 5B and FIG. 5C may be collectively referred to as FIG. 5 herein.

FIG. 6A (FIG. 6A) is a schematic illustration of a cut-away portion of a modular coater, shown in horizontal cross-section, as viewed from a top of the coater. FIG. 6B (FIG. 6B) is a schematic illustration of a cut-away portion of a modular coater, shown in vertical cross-section, as viewed from a side of the coater. FIG. 6A and FIG. 6B may be collectively referred to as FIG. 6 herein.

FIG. 7A (FIG. 7A) is a schematic illustration of a pump compartment, shown in horizontal cross-section, as viewed from a top of the compartment. FIG. 7B (FIG. 7B) is a schematic illustration of a pump compartment, shown in vertical cross-section, as viewed from an end of the compartment. FIG. 7A and FIG. 7B may be collectively referred to as FIG. 7 herein.

FIG. 8A (FIG. 8A) is a schematic illustration of a pump compartment, shown in horizontal cross-section, as viewed from a top of the compartment. FIG. 8B (FIG. 8B) is a schematic illustration of a pump compartment, shown in one vertical cross-section, as viewed from an end of the compartment. FIG. 8C (FIG. 8C) is a schematic illustration of a pump compartment, shown in another vertical cross-section, as viewed from an end of the compartment. FIG. 8A, FIG. 8B and FIG. 8C may be collectively referred to as FIG. 8 herein.

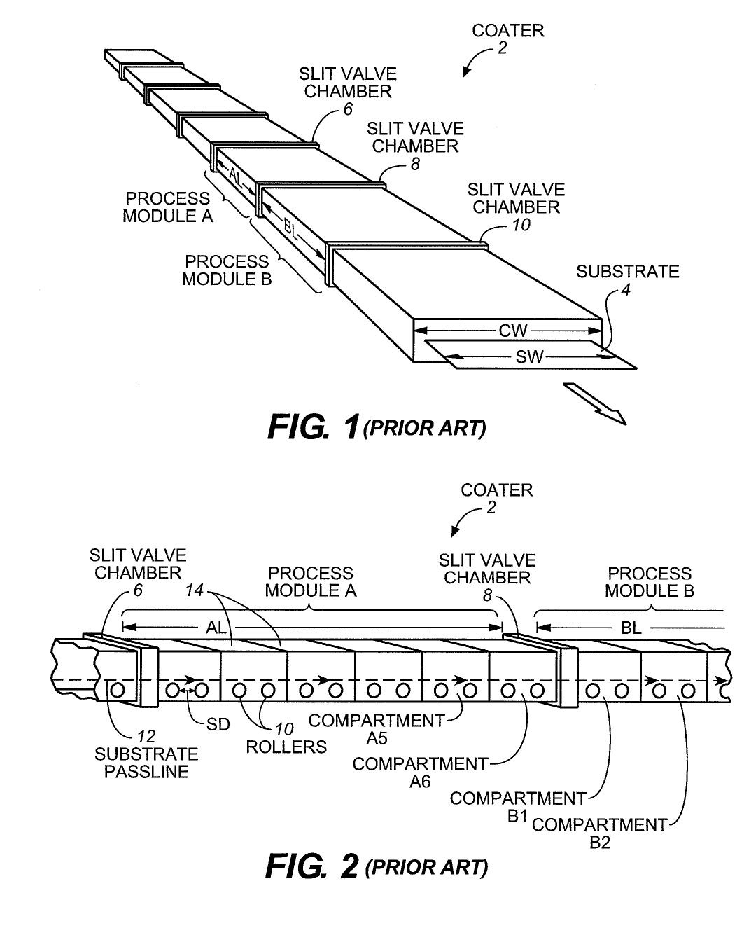

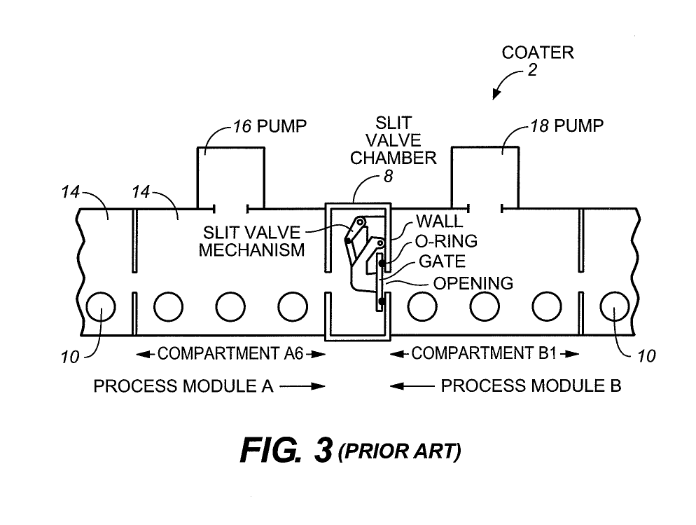

### DESCRIPTION

In this description, it will be understood that a word appearing in the singular encompasses its plural counterpart, and a word appearing in the plural encompasses its singular counterpart, unless implicitly or explicitly understood or stated otherwise. Further, it will be understood that for any given component described herein, any of the possible candidates or alternatives listed for that component, may generally be used individually or in any combination with one another, unless implicitly or explicitly understood or stated otherwise. Additionally, it will be understood that any list of such candidates or alternatives, is merely illustrative, not limiting, unless implicitly or explicitly understood or stated otherwise. Still further, it will be understood that any figure or number or amount presented herein is approximate, and that any numerical range includes the minimum number and the maximum number defining the range, whether the word “inclusive” or the like is employed or not, unless implicitly or explicitly understood or stated otherwise. Yet further, it will be understood that any heading employed is by way of convenience, not by way of limitation. Additionally, it will be understood that any permissive, open, or open-ended language encompasses any relatively permissive to restrictive language, less open to closed language, or less open-ended to closed-ended language, respectively, unless implicitly or explicitly understood or stated otherwise. Merely by way of example, the word “comprising” may encompass “comprising”-, “consisting essentially of”-, and/or “consisting of”-type language.

Various terms are generally described or used herein to facilitate understanding. It will be understood that a corresponding general description or use of these various terms applies to corresponding linguistic or grammatical variations or forms of these various terms. It will also be understood that a general description or use or a corresponding general description or use of any term herein may not apply or may not fully apply when the term is used in a non-general or more specific manner. It will also be understood that the terminology used herein, or the descriptions thereof, for the description of particular embodiments, is not limiting. It will further be understood that embodiments described herein or applications described herein, are not limiting, as such may vary.

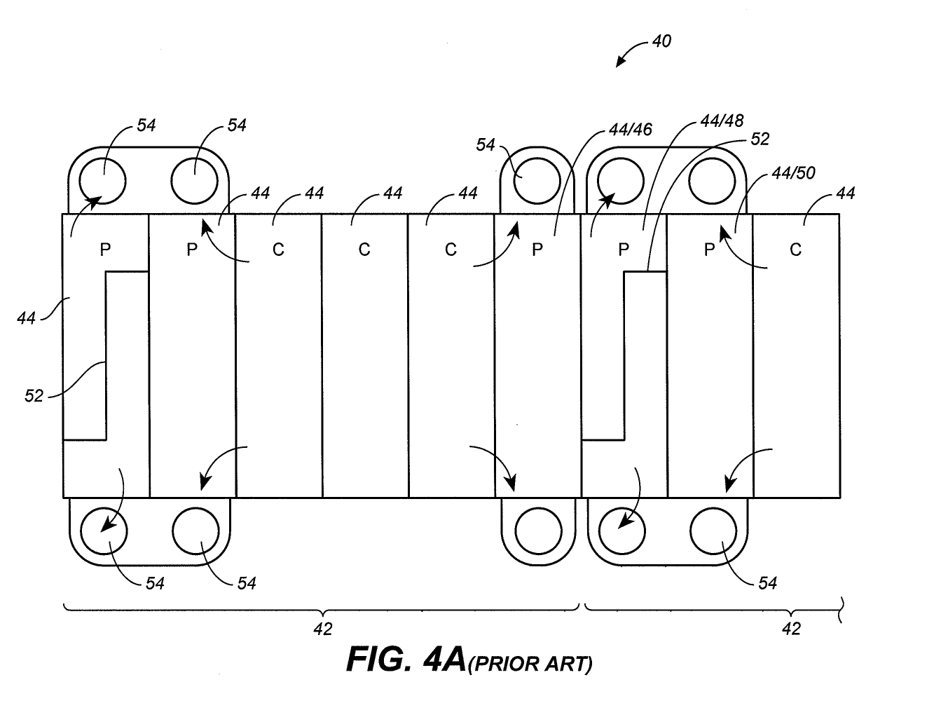

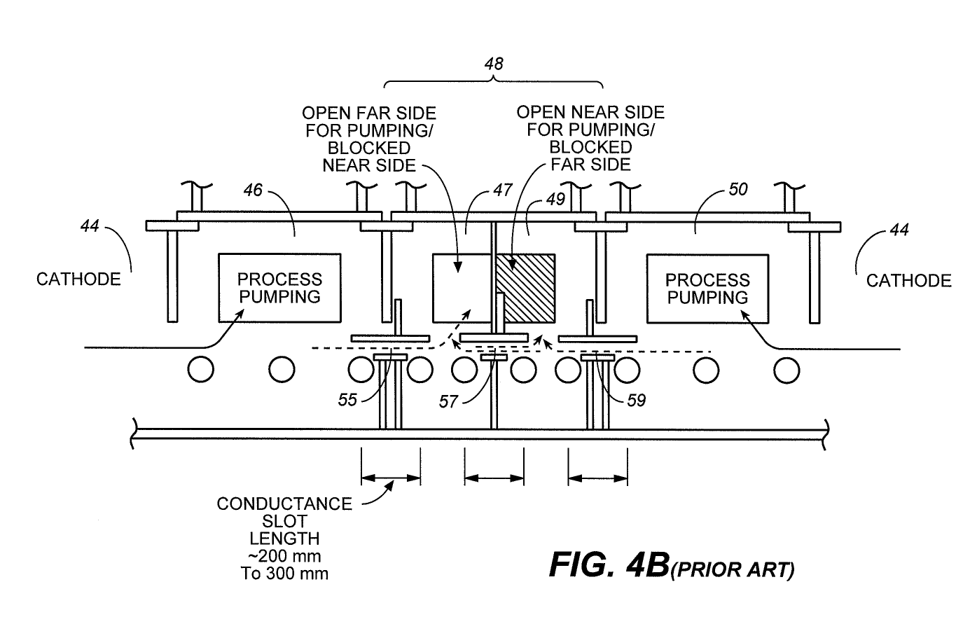

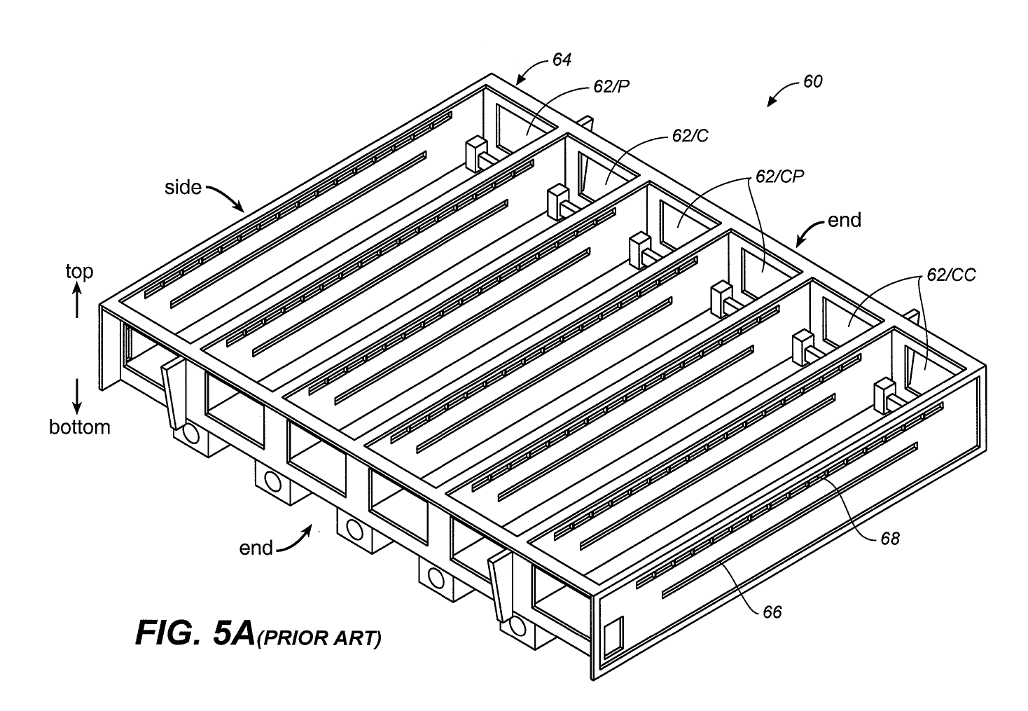

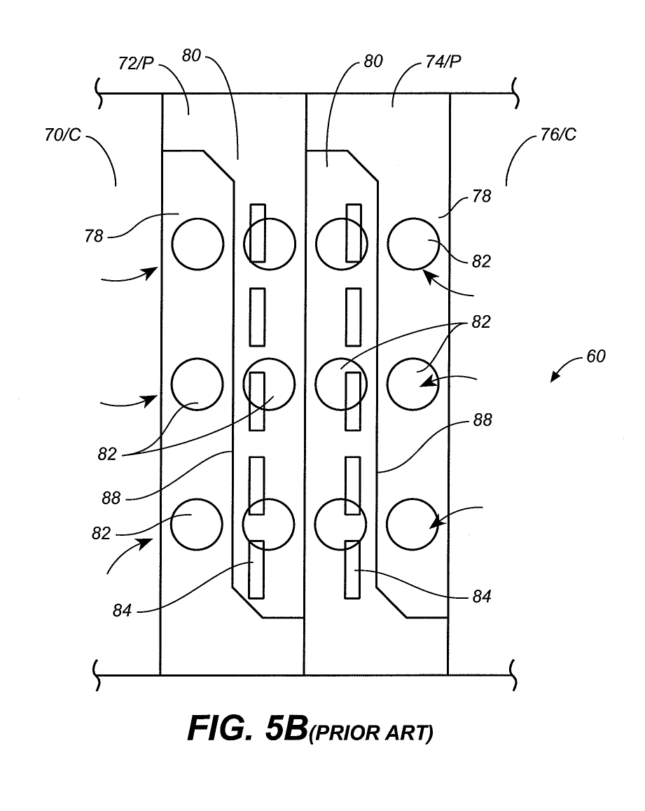

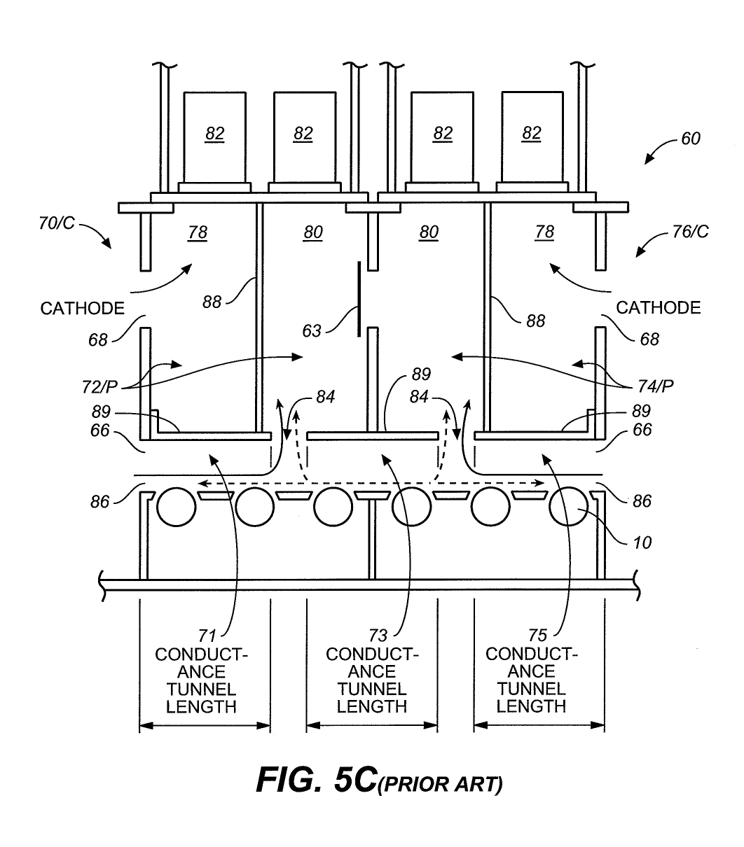

As shown in FIG. 4, a coater 40 may be comprised of at least one process module 42, which has a number of compartments or bays 44. A modular coater may be configured in a certain way, such as with established process compartments and pump compartments of uniform size, and may not be amenable to reconfiguration. By way of example, a modular coater 40 may be configured with process modules 42 of a set configuration, from an upstream end to a downstream end, of a pump compartment (P), another pump compartment (P), a number of process or coat compartments, such as three such compartments (CCC), for example, and a further pump compartment (P), resulting in a set configuration (PPCCCP, for example) of six compartments 44. A coater for large substrates, such as architectural glass, may be configured with one such process module after another. A suitable slit valve or slit valve chamber, such as any of those shown in U.S. patent application Ser. No. 11/150,360, entitled “Dual Gate Isolating Maintenance Slit Valve Chamber with Pumping Option,” which is hereby incorporated by reference in its entirety, for example, any of those shown and described in relation to FIGS. 5-9 of that application, may be employed between adjacent process modules.

The overall coater may thus have a set configuration (PPCCCP/PPCCCP/PPCCCP, etc., as shown, PCCCPP/PCCCPP/PCCCPP, etc., or the like) of adjacent process modules. Such a multi-module coater, shown in part in FIG. 4, may thus include a configuration of five compartments or bays (CP/PPC, as shown, CPP/PC, or the like). Each of the two pump compartments 46 and 50 arranged adjacent a coat compartment in a multi-modular configuration (CP/PPC, as shown) may be used to pump the adjacent coat compartment, as schematically indicated by the arrows associated with the pump compartments 46 and 50 shown in FIG. 4, and the remaining pump compartment 48, sometimes called an isolation bay, arranged between the two pump compartments 46 and 50 in the multi-modular configuration, may be used to pump the pathway (not shown) associated with passage of the substrate through the pump compartments 46, 48 and 50. Appropriate baffling 52 may be employed within the isolation bay 48, such that portions or half bays of the isolation bay are pumped separately, as schematically indicated by the arrows associated with the isolation bay 48 shown in FIG. 4. The baffling 52 may also be referred to as an internal plenum that creates isolation tunnels within the pump compartment 48. Each of the pump compartments may be equipped with two diffusion pumps 54, which, because of their large footprint, may be supported vertically, one on each end of the compartment, as shown.

In the modular coater just described, the diffusion pumps 54 are generally high speed, hot oil vacuum pumps, generally advantageous relative to a turbomolecular pump in terms of relatively high pump capacity or pump speed and low expense, and generally disadvantageous relativelto a turbomolecular pump in terms of potential oil contamination, relatively high power requirement (for example, 9 kW per pump) and large footprint. Merely by way of example, a hot oil pump, which may have a capacity of about 9000 liters per second, for example, is generally associated with a large footprint, particularly in view of the associated trenching that is generally located along the side of a coating system in order to accommodate the height of the pump. This large footprint has associated facility costs. Further by way of example, while oil contamination associated with a hot oil pump generally occurs only during a failure mode, it is associated with labor-intensive clean-up, and thus, another facility cost.

In such a modular coater, at least three full pump compartments (P/PP, for example) are used to provide an acceptable level of gas isolation, where desirable or needed, between process or coat compartments. Each of the fluid communication or gas conductance slots 55, 57 and 59, as shown in FIG. 4B, associated with each of the three full pump compartments 46, 48 and 50, may correspond to about 200 to about 300 millimeters of length. Such conductance slots may be referred to as conductance tunnels. A gas isolation ratio of from about 20 to about 30 to one, where the gas isolation ratio is a ratio of the pressure of a gas in the coat compartment upstream of the three full pump compartments to the pressure of that gas in the coat compartment downstream of the three full pump compartments, may be accomplished with such a modular coater, wherein process pumping occurs in pump compartments 46 and 50 and gas isolation pumping occurs in pump compartment 48, via the half bays 47 and 49 thereof, that have access to the gas conductance slots 55, 57 and 59, as shown. As mentioned previously, appropriate baffling 52 may be employed to facilitate the gas isolation, such as baffling that provides half bay 47 with access to the gas conductance slots 55 and 57 on the far side (the upper-most portion shown in FIG. 4A) of the compartment, while blocking access to these slots on the near side (the lower-most portion shown in FIG. 4A) of the compartment, and that provides half bay 49 with access to the gas conductance slots 57 and 59 on the near side (the lower-most portion shown in FIG. 4A) of the compartment, while blocking access to these slots on the far side (the upper-most portion shown in FIG. 4A) of the compartment.

A modular coater may be designed for greater flexibility in terms of configuration and reconfiguration. An example of such a modular coater is the VAC 870 coater commercially available from Applied Films Corporation (Fairfield, Calif.). A schematic illustration of a structure 64 of such a modular coater 60 is shown in FIG. 5A, from an elevated view of the top, a side, and a downstream end of the coater. As shown, the compartments 62 may be of substantially uniform size, which facilitates configuration and/or reconfiguration of the process modules, and thus the overall coater. As such, the coater 60 may be referred to as a modular, compartment-type coater. The compartments 62 may be used for similar or different purposes, whether coating, pumping or some other purpose. The structure 64 of the compartment coater 60 is depicted as an open structure, having no top structures or covers and no end structures or covers for the compartments 62. The open structure 64 is quite flexible and may be configured or reconfigured in a manner suitable for a particular application by simply adding top structures and end structures suitable for the application at hand. Merely by way of example, a top structure (not shown) that closes or seals the top of a compartment 62, while permitting access to a compartment, such as pump access, for example, and similarly, an end structure (not shown) that closes or seals an end of a compartment 62, while permitting access to a compartment, such as pump access, for example, may be added to the open structure. Further, merely by way of example, modules, such as pump modules or coating modules, for example, may be associated with a compartment, such as a top of a compartment, for example, as described in U.S. Provisional Patent Application No. 60/682,985 of Philip M. Petrach, entitled “Modular Coating System” and filed on May 20, 2005, and co-pending U.S. patent application No. ______ of Philip M. Petrach, entitled “Module for a Coating System and Associated Technology” and filed on May 8, 2006, each of which is incorporated herein in its entirety by this reference. As shown, each of the compartments 62 of the open structure 64 has an opening or slot 66 for passage of a substrate through the compartment and openings or slots 68 for fluid communication associated with the compartment, such as that associated with pumping.

By way of example, a modular coater 60 may be configured with process modules 62 of a set configuration, from an upstream end to a downstream end, of a pump compartment (P), a number of coat compartments, such as two such compartments (CC), for example, and another pump compartment (P), resulting in a set configuration (PCCPCC, for example) of six compartments 62, as shown in FIG. 5A. In such a case, where one pump compartment is flanked by adjacent coat compartments, one on the upstream side of the pump compartment and the other on the downstream side of the pump compartment, the pump compartment is sufficient to pump the process gas from the upstream side and the process gas from the downstream side. In such a case, however, the single pump compartment is generally not sufficient to provide acceptable or desirable gas isolation, particularly when the upstream process gas and the downstream gas differ or are incompatible, being associated with a gas isolation ratio of about 5 to one at the most.

Further by way of example, a coater for large substrates, such as architectural glass, may be configured with one such process module after another, each with the same or a different configuration of coat and pump compartments, such that the overall coater has a set configuration (PCCPCC/PCPPCP/PCCPCP, etc., for example) of adjacent process modules. In such a case, where one pump compartment is flanked by adjacent coat compartments, one on the upstream side and the other on the downstream side, the pump compartment is generally not sufficient to provide acceptable or desirable gas isolation, as previously described. In such a case, however, where two adjacent pump compartments are flanked by adjacent coat compartments, one on the upstream side of the upstream pump compartment and one on the downstream side of the downstream pump compartment, as shown in FIGS. 5B and 5C, the two pump compartments may provide acceptable gas isolation, as further described below.

A modular compartment-type coater 60, shown in part in FIGS. 5B and 5C, may include a configuration of four compartments or bays (CPPC, C/PPC, or CPP/C, for example), from an upstream end to a downstream end, of a process or coat compartment 70, two pump compartments 72 and 74, and another coat compartment 76. As shown in FIG. 5C, merely by way of example, a suitable slit valve 63 or slit valve chamber may be employed between adjacent process modules, as previously described. Each of the pump compartments 72 and 74 may be equipped with up to six turbomolecular pumps 82, generally spinning rotor pumps with high vacuum, which may be supported on the top of the compartment. Each of the pump compartments 72 and 74 comprises two half bays, namely, one half bay 78 adjacent a coat compartment, equipped with up to three pumps 82, for pumping the adjacent coat compartment, and the other half bay 80 adjacent the aforementioned half bay 78, also equipped with three pumps 82, for pumping the pathway 86 associated with passage of the substrate through the compartment, as shown collectively in FIG. 5. By way of example, one half bay 78 (the left-most half bay 78 in FIG. 5B and 5C) may be used to pump adjacent coat compartment 70, which comprises a cathode or target, and another half bay 78 (the right-most half bay 78 in FIG. 5B and 5C) may be used to pump adjacent coat compartment 76, which comprises a cathode or target. The pumping of the coat compartments may be accomplished via openings or slots 68, as previously described. Appropriate baffling 88 may be employed within the pump compartments 72 and 74, such that portions or half bays of these compartments are pumped separately. Further by way of example, one half bay 80 (the left-most half bay 80 in FIG. 5B and 5C) may be used to pump the pathway between conductance slot 71 and conductance slot 73, and another half bay 80 (the right-most half bay 80 in FIG. 5B and 5C) may be used to pump the pathway between conductance slot 73 and conductance slot 75. The pumping of the pathway 86 may be accomplished via openings or slots 84. Appropriate baffling 89 may be employed within the pump compartments 72 and 74, such that portions or various conductance slots of the pathway are pumped separately.

In the modular compartment coater just described, two full pump compartments 72 and 74 are employed to provide appropriate gas isolation in association with three conductance slots 71, 73 and 75. The conductance slots 71, 73 and 75 may be of lengths as shown in FIG. 5C, which may be the same, approximately the same, or different. The conductance slot lengths, or the overall length of the conductance slots together, may be factors in determining the gas isolation ratio associated with the pump compartments 72 and 74, or the half bays thereof. The length of a conductance slot may be about 400 millimeters to about 500 millimeters, the total length of three conductance slots may be about 1450 millimeters (not including the length (about 150 millimeters) of each of the two openings or gaps between adjacent conductance slots), and the range of a gas isolation ratio may be about 20 to about 30 to one, depending on the number of pumps employed or the pumping capacity associated with the two openings 84.

In the modular compartment coater just described, the turbomolecular pumps 82 are generally advantageous relative to diffusion pumps in terms of relatively low power requirement (for example, 1 kW or less per pump) and small footprint, and generally disadvantageous relative to diffusion pumps in terms of relatively low pump capacity or pump speed and high expense (such as 2.5 times more expensive, for example). Merely by way of example, as turbomolecular pumps are generally mounted on the top of a compartment, there is generally no side-mounted trenching and associated footprint, such as that associated with diffusion pumps. In the modular compartment coater just described, at least two full pump compartments are employed to provide an acceptable level of gas isolation, where desirable or needed, between process or coat compartments. The two full pump compartments 72 and 74 of FIG. 5 may correspond to about 1400 to about 1800 millimeters of length and a gas isolation ratio of from about 25 to about 35 to one, such as from about 25 to about 30 to one, for example, where the gas isolation ratio is a ratio of the pressure of a gas in the adjacent coat compartment 70 to the pressure of that gas in the adjacent coat compartment 76.

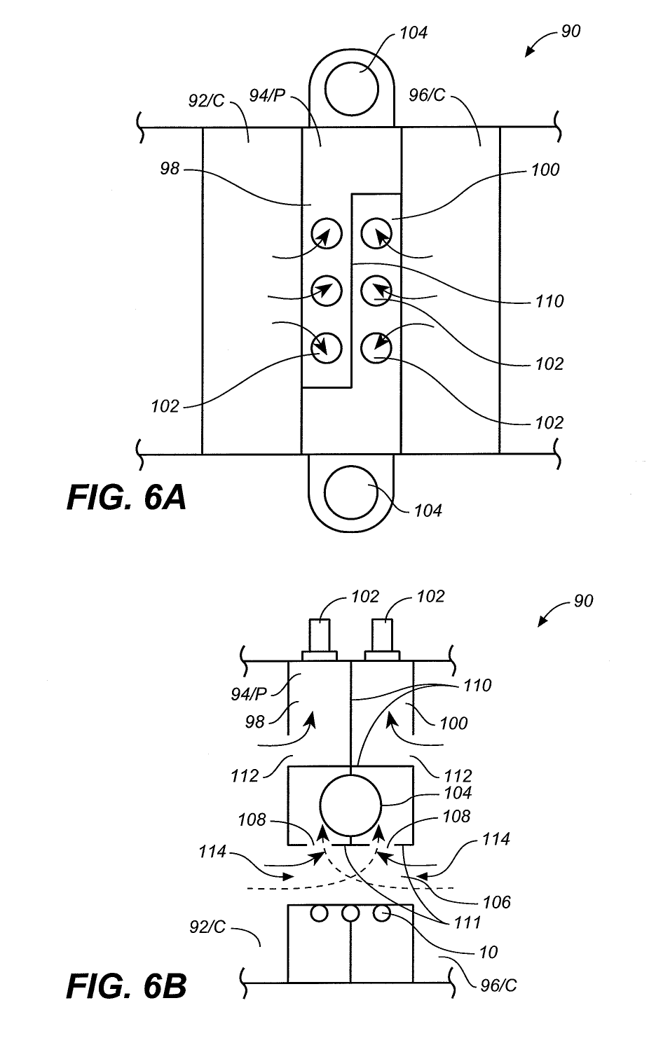

According to an embodiment, a multi-module coater 90, shown in part in FIG. 6A and FIG. 6B, may include a configuration of three compartments or bays (CPC, C/PC or CP/C, for example), from an upstream end to a downstream end, of a process or coat compartment 92, a pump compartment 94, and another coat compartment 96. The substrate may pass through the coater 90 and the pump compartment 94 via a gap or slot 114 in the sides of the pump compartment 94. When the substrate to be coated is thin, such as a thin sheet of glass, for example, the slot 114 may be only slightly larger than the thickness of the glass, such that at the working pressure used in the coating process, the narrow slot effectively impedes gas flow.

The pump compartment 94 may be equipped with up to six turbomolecular pumps 102, which may be supported on the top of the compartment, and two diffusion pumps 104, one supported on one end of the compartment and the other supported on the other end of the compartment, vertically, for example. The pump compartment 94 may comprise two half bays, namely, one half bay 98 adjacent the coat compartment 92, equipped with up to three turbomolecular pumps 102, for pumping the coat compartment 92, and the other half bay 100 adjacent the aforementioned half bay 98 and the coat compartment 96, also equipped with up to three pumps 102, for pumping the coat compartment 96. The pumping of the coat compartments may be accomplished via openings or slots 112, as previously described and as collectively shown in FIG. 6. The diffusion pumps 104 associated with pump compartment 94 may be employed to pump the pathway 106 associated with passage of the substrate through the compartment, as collectively shown in FIG. 6. A diffusion pump 104 may be associated with the half bay 98 and another diffusion pump 104 may be associated with the half bay 100, as collectively shown in FIG. 6. The pumping of the pathway 106 may be accomplished via openings or slots 108, as previously described. Appropriate baffling 110 and appropriate baffling 111 may be employed within the pump compartment 94, such that portions of the half bays of these compartments are pumped separately, and such that portions or various conductance slots of the pathway are pumped separately, respectively.

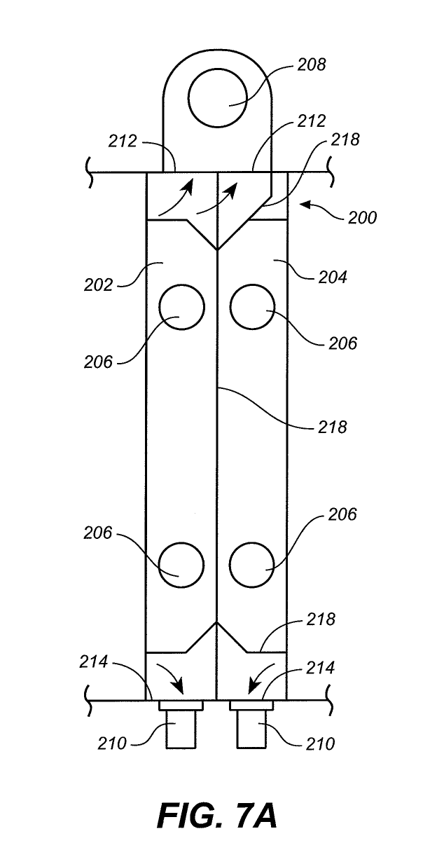

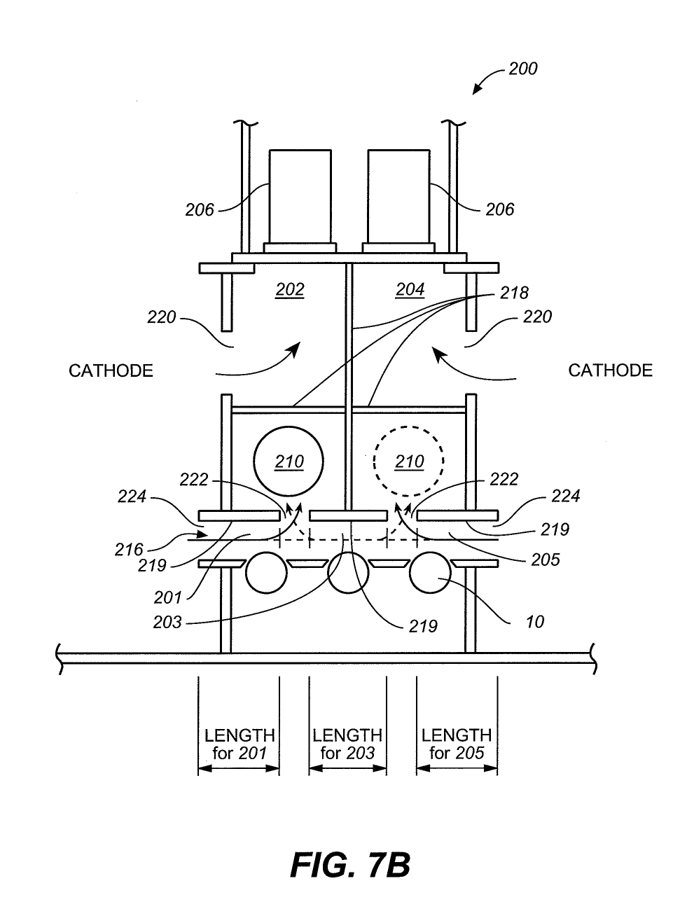

In the coater just described, a single pump compartment 94 may be employed to provide appropriate gas isolation in association with three conductance slots (not shown). The conductance slots may be configured in a manner similar to conductance slots 201, 203 and 205 of FIG. 7B, which is further described herein. The conductance slots may be of lengths such as those shown in FIG. 7B, which may be the same, approximately the same, or different. The conductance slot lengths, or the overall length of the conductance slots together, may be factors in determining the gas isolation ratio associated with the pump compartment 94, or the half bays thereof. Merely by way of example, the length of a conductance slot may be from about 200 to about 300 millimeters, such as about 250 millimeters, for example, the total length of three conductance slots (not including the length (about 150 millimeters) of each of the two openings or gaps between adjacent conductance slots) may be from about 700 millimeters to about 900 millimeters, such as about 770 millimeters, for example, and the range of a gas isolation ratio may be about 20 to about 35 to one, such as about 20 to about 30 to one, for example, depending on the number of pumps employed or the pumping capacity associated with the two openings 222.

In such a coater, a single pump compartment may be employed to provide an acceptable level of gas isolation, where desirable or needed, between process or coat compartments. A single slot conductance length associated with such a compartment may correspond to about 200 to about 250 millimeters of length. It is contemplated that when used in a coater, the single pump compartment may correspond to a gas isolation ratio of more than about 20 to one, such as up to about 35 to one, for example. Use of a single pump compartment in the manner just described may be advantageous in terms of reductions in equipment costs, coater footprint, configuration time and effort, operational time and effort, and coater complexity, and/or the like, and particularly advantageous in the context of large, multi-module coaters, such as those employed to coat a substrate with five or more layers of material, such as six to eight layers of material, for example, which have heretofore employed or required a significant number of gas isolation compartments.

It is contemplated that a variety of multi-module coaters that comprise a configuration of three compartments or bays, in which a single pump compartment is flanked by two coat compartments, such as that just described, may be useful. According to an embodiment that is illustrated in FIG. 7A and FIG. 7B, such a single pump compartment 200 may comprise two half bays, namely, one half bay 202 which may be located adjacent a coat compartment (not shown) and another half bay 204 adjacent the aforementioned half bay 202 which may be located adjacent another coat compartment (not shown). The substrate (not shown) to be coated may pass through the pump compartment 200 via a gap or slot 224 associated with the sides of the pump compartment, as previously described. Each of half bays 202 and 204 may be equipped with up to three turbomolecular pumps 206, which may be supported on the top of the half bay, for pumping an adjacent coat compartment. Each half bay may be equipped with a diffusion pump 208, which may be supported on an end 212 of the half bay, and up to two turbomolecular pumps 210, which may be supported on another end 214 of the half bay, for pumping the pathway 216 associated with passage of the substrate through the compartment, as collectively shown in FIG. 7. In FIG. 7A, two turbomolecular pumps 206 are shown in association with each half bay, only the diffusion pump 208 associated with half bay 202 can be seen, and only one turbomolecular pump 210 per half bay can be seen. The pumping of adjacent coat compartments (not shown) and the pathway 216 may be accomplished via openings or slots 220 and 222, respectively, as previously described. Appropriate baffling 218 and appropriate baffling 219 may be employed within the pump compartment 200, such that portions of the half bays of these compartments are pumped separately, and such that portions or various conductance slots of the pathway are pumped separately, respectively.

In the coater just described, a single pump compartment 200 may be employed to provide appropriate gas isolation in association with the three conductance slots 201, 203 and 205. The conductance slots 201, 203 and 205 may be of lengths as shown in FIG. 7B, which may be the same, approximately the same, or different. The conductance slot lengths, or the overall length of the conductance slotss together, may be factors in determining the gas isolation ratio associated with the pump compartment 200, or the half bays thereof. These parameters may be as previously described in relation to FIG. 6, for example. It is contemplated that a single pump compartment may be employed in a coater to provide an acceptable level of gas isolation, where desirable or needed, between process or coat compartments. Further, it is contemplated that such a pump compartment may correspond to the length and gas isolation ratio described above in relation to the pump compartment associated with FIG. 6.

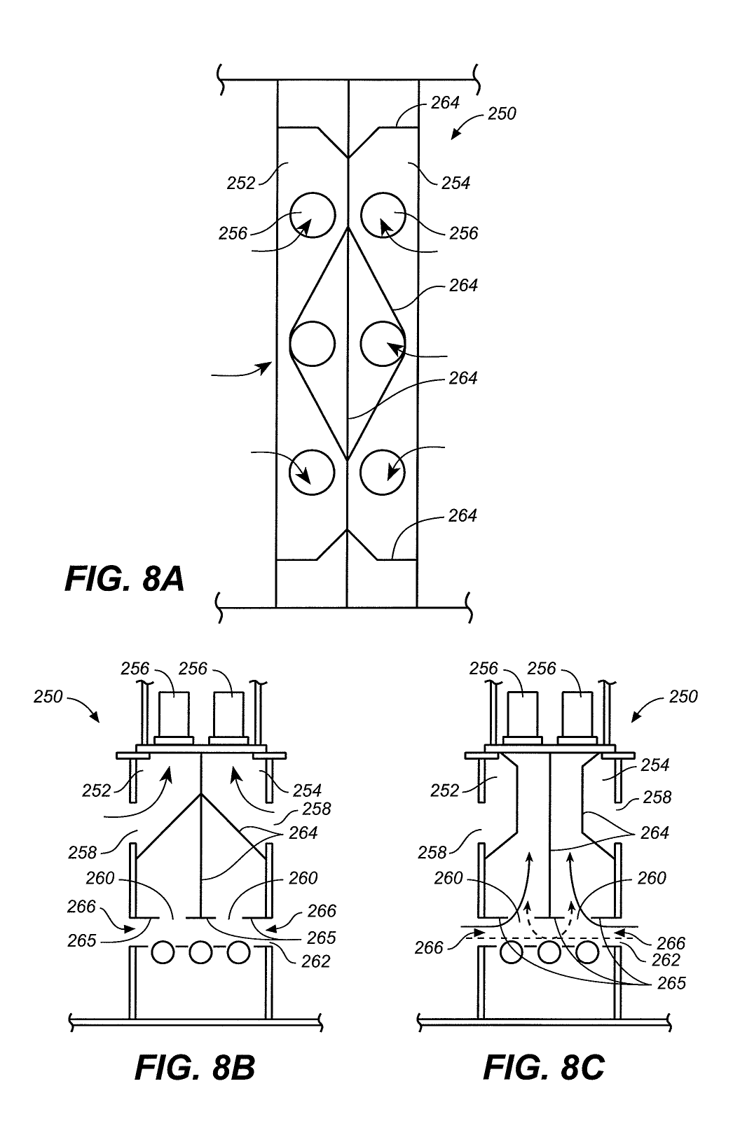

According to another embodiment, a single pump compartment 250 that is illustrated in FIG. 8A, FIG. 8B and FIG. 8C may be flanked by two coat compartments (not shown), as previously described. The substrate (not shown) to be coated may pass through the pump compartment 250 via a gap or slot 266 associated with the sides of the pump compartment, as previously described. The pump compartment 250 may comprise two half bays, namely, one half bay 252 which may be located adjacent a coat compartment (not shown) and another half bay 254 adjacent the aforementioned half bay 252 which may be located adjacent another coat compartment (not shown). Each half bay may be equipped with up to three turbomolecular pumps 256, which may be supported on the top of the half bay, for pumping an adjacent coat compartment and for pumping the pathway associated with passage of the substrate through the compartment, as collectively shown in FIG. 8. The pumping of the coat compartments (not shown) and the pathway 262 may be accomplished via openings or slots 258 and 260, respectively, as previously described. Appropriate baffling 264 and appropriate baffling 265 may be employed within the pump compartment 250, such that portions of the half bays of these compartments are pumped separately, and such that portions or various conductance slots of the pathway are pumped separately, respectively, as shown in FIG. 8. Merely by way of example, four of the turbomolecular pumps 256 may be used to pump adjacent coating compartments, while the remaining two of the turbomolecular pumps 256 may be used to pump the pathway 262.

In the coater just described, a single pump compartment 250 may be employed to provide appropriate gas isolation in association with three conductance slots (not shown). The conductance slots may be configured in a manner similar to conductance slots 201, 203 and 205 of FIG. 7B, as previously described. The conductance slots may be of lengths such as those shown in FIG. 7B, which may be the same, approximately the same, or different. The conductance slot lengths, or the overall length of the conductance slots together, may be factors in determining the gas isolation ratio associated with the pump compartment 94, or the half bays thereof. These parameters may be as previously described in relation to FIG. 6, for example. It is contemplated that a single pump compartment may be employed in a coater to provide an acceptable level of gas isolation, where desirable or needed, between process or coat compartments. Further, it is contemplated that such a pump compartment may correspond to the length and gas isolation ratio described above in relation to the pump compartment associated with FIG. 6.

In connection with an apparatus described or contemplated herein, it will be understood that pumps other than diffusion pumps and turbomolecular pumps, such as cryogenic pumps or other high vacuum pumps, for example, may be used, provided they are suitable for the pumping application. Any such pump may alone, or in combination with other pumps, have a capacity appropriate for achieving approximately high vacuum conditions in a target area, such as about 10⁻³ Torr to about 10⁻⁷ Torr or about 10⁻⁸ Torr, such as about 10⁻⁴ Torr or less, for example, or pressures associated with molecular or transitional flow regimes. Additionally, it will be understood that any suitable combination and/or number of pumps may be used. Merely by way of example, in general, where a pump has a sufficiently small footprint and/or sufficiently small or relatively non-cumbersome support requirements, a greater number of such pumps may be used relative to a number of pumps having a larger footprint or greater or more cumbersome support requirements. It will be understood that the pumps may be configured relative to a pump compartment in any suitable manner, and at any suitable location. For example, it will be understood that any suitable manner of mounting or supporting of any suitable pump or pumps, such as via a top and/or a bottom (if feasible) and/or an end of a compartment, and/or the like, may be employed. Further, it will be understood that any suitable pump or combination of pumps may be used in association with the pumping of the substrate pathway and/or with the pumping of one or more coat compartments.

It will be understood that any suitable form of baffling or internal plenum(s) may be employed to separate portions of compartments as desirable or necessary. Baffling, comprising at least one baffle, may be arranged to divide a compartment into separate sections. Separate pumping may be associated each of the separate sections. For example, in the embodiments of FIGS. 6-8, the full pump compartment is split into four separate sections, each having its own pumping arrangement. As shown, two of the sections may be dedicated to pumping process gas from adjacent compartments and two of the sections may be dedicated to pumping gas from the pathway or conductance slots for gas isolation. One of the two gas isolation sections may be associated with or reside between a set of two of three total conductance slots and the other may be associated with or reside between another set of two of three total conductance slots. The three conductance slots may be of similar or different length. Baffling may be used to associate a gas isolation section or stage to either the side or the top of the coater, or any other appropriate part of the coater, where pumping generally occurs. Baffling may be used to separate a process pumping section or stage from another process pumping section stage, and/or from a gas isolation section or stage. Baffling may be employed to more or less isolate or seal one section or stage from another to reduce or to minimize cross-talk or cross-contamination therebetween. Baffling associated with a section or stage should be such that only about 5% or less of the cross-sectional area of the opening to the pump that is associated with that section or stage allows gas leakage or cross-talk. For example, if pump slots associated with a process pump stage or a gas isolation stage have a total cross-sectional area of 600 square inches, gaps or openings in baffling associated with the stage should have a total cross-sectional area of about 30 square inches or less.

According to an embodiment, the pumps of the apparatus may comprise at least one diffusion pump for pumping gas from the pathway associated with passage of the substrate through the pump compartment and at least one pump that is other than a diffusion pump for pumping gas from at least one of the process compartments that flanks the pump compartment. The latter of these pumps may be a turbomolecular pump, for example. Merely by way of example, at least two of the latter pumps may be employed.

According to another embodiment, the pumps of the apparatus may comprise at least one pump that is in operable communication with the pump compartment via an end of the pump compartment. Such a pump may be used to pump gas from the pathway, merely by way of example. Further, merely by way of example, such a pump may comprise any suitable pump, such as a diffusion pump, a turbomolecular pump, or a cryopump, for example. Where more than one such pump is employed, the pumps may comprise any suitable pumps, such as a diffusion pump, a turbomolecular pump, a cryopump, and/or any combination thereof, for example.

According to another embodiment, the pumps of the apparatus may comprise at least one pump that is in operable communication with the pump compartment via a top of the pump compartment. Such a pump may be used to pump gas from at least one of the process compartments that flanks the pump compartment, merely by way of example. Further, merely by way of example, such a pump may comprise any suitable pump, such as a diffusion pump or a turbomolecular pump, for example. Where more than one such pump is employed, the pumps may comprise any suitable pumps, such as a diffusion pump, a turbomolecular pump, and/or any combination thereof, for example. Merely by way of example, at least two such pumps may be employed.

According to an embodiment, pumps of the apparatus may comprise at least one diffusion pump in operable communication with the pump compartment via an end of the pump compartment for pumping gas from the pathway associated with passage of the substrate through the pump compartment, and/or at least one turbomolecular pump in operable communication with another end of the pump compartment for pumping gas from the pathway, and at least one turbomolecular pump in operable communication with the pump compartment via a top of the pump compartment for pumping gas from at least one of the process compartments that flanks the pump compartment. Merely by way of example, at least two of the latter turbomolecular pumps may be employed for pumping gas from the pump compartment(s). An example of such a pumping configuration is provided in FIG. 7.

According to another embodiment, pumps of the apparatus may comprise turbomolecular pumps in operable communication with the pump compartment via a top of the pump compartment for pumping gas from the pathway associated with passage of the substrate through the pump compartment, a process compartment that flanks the pump compartment, and another process compartment that flanks the pump compartment. An example of such a pumping configuration is provided in FIG. 8.

According to an embodiment, the pump compartment of the apparatus may comprise at least one baffle separating an area of the pump compartment associated with pumping gas from a process compartment that flanks the pump compartment and another area of the pump compartment associated with pumping gas from another process compartment that flanks the pump compartment. According to another embodiment, the pump compartment of the apparatus may comprise at least one baffle separating an area of the pump compartment associated with pumping gas from the pathway associated with passage of the substrate through the pump compartment and another area of the pump compartment associated with the pumping of gas from at least one process compartment that flanks the pump compartment. Examples of such pump compartments are provided in FIGS. 6-8.

An apparatus for coating a substrate passing therethrough is provided. The apparatus may comprise a process or coating compartment sufficient for passage of the substrate therethrough via a path of a length that extends from an entrance to an exit of the compartment. This process or coating compartment is sufficient for coating a substrate via a gas, which may comprise one or more component gas(es), that is employed in the coating process. The apparatus may, and typically does, comprise several such process or coating compartments for coating a substrate in this manner. The gas used in one such compartment may be the same or different than that used in another such compartment. It is possible to isolate the gases, be they the same or different, that are used in different process compartments via a suitable pump compartment, such as any of the isolation pump compartments described above in relation to FIGS. 6-8. The pump compartment is disposed between one process compartment and another process compartment and is sufficient for passage of a substrate therethrough via a pathway of a length that extends from an entrance to an exit of the compartment. This pathway is operable communication with the paths associated with the two process compartments, such that a substrate may pass through all three compartments, as may be accomplished via rollers, as previously described.

The pump compartment is in operable communication with each of the two process compartments as well as the pathway that extends the length of the pump compartment, such that gas may be pumped from the compartments and the pathway via pumps. Sufficient pumping may be achieved using less than two full-size pump compartments, such as one full-size pump compartment, for example. Merely by way of example, when the process compartments are of the same size, such that the path lengths described above are the same, a pump compartment having a pathway length or multiple pump compartments having a collective pathway length that is less than two times the path length of either process compartment, may be employed. Further merely by way of example, when the process compartments and the pump compartment are of the same size, such that the path lengths and the pathway length described above are the same, a pump compartment that is, or multiple pump compartments that collectively are, shorter in length than two full-size pump compartments, may be employed. Still further, merely by way of example, when the process compartments are of different sizes, a pump compartment that is, or multiple pump compartments that collectively are, shorter in length than two times the average length of the two process compartments, may be employed.

It is contemplated that such a pump compartment is, or such pump compartments are, sufficient for approximately isolating the gas used in one of the process compartments from the gas used in another of the process compartments. An appropriate level of gas isolation may vary from process to process and from user to user. Generally, an acceptable level of gas isolation between two process compartments that employ the same gas environment or similar, compatible gas environments may be represented by gas isolation ratios from about 1 to 1 to about 6 to 1, for example. Generally, an acceptable level of gas isolation between two process compartments that employ different or incompatible gas environments may be represented by gas isolation ratios from about 20 to 1 to about 35 to 1, for example. It is contemplated that pump configurations described or contemplated herein are sufficient for more optimal gas isolation ratios that may be associated with further developments, such as the development of more sensitive coatings, for example. While a single such pump compartment is sufficient for approximate gas isolation in a coating apparatus or coating process, it is contemplated that at least one further such pump compartment may be employed. The use of fewer or smaller pump compartments may be useful or desirable for a variety of reasons, such as reduction of equipment footprint, reduction of process time and complexity, reduction of operational and configuration costs, and/or the like, merely by way of example. The use of a greater number of pump compartments may be useful or desirable for redundancy or greater gas isolation capability, merely by way of example. A choice as to how many pump compartments are to be used in a coating system may involve finding an appropriate balance in view of the foregoing factors and other applicable considerations.

As just described, it is contemplated that a pump compartment such as any of the isolation pump compartments described above in relation to FIGS. 6-8 is, or multiple such pump compartments are, sufficient for approximately isolating the gas used in one of the process compartments from the gas used in another of the process compartments. Merely by way of convenience, one such pump compartment contemplated as being sufficient for such approximate gas isolation is now described. It is contemplated that such a pump compartment that is flanked by two process compartments, as described herein, may be sufficient to provide a ratio of a pressure of a gas in one of the process compartments and a pressure of that gas in the other of the process compartments of at least about 20 to one in association with the substrate coating process. Merely by way of example, it is contemplated that such a ratio may be on the order of from about 20 to one or 25 to one to about 35 to one, or greater. In a coating apparatus, such a pump compartment may be flanked by a series of process compartments on either side or on both sides of the pump compartment. Merely by way of example, it is contemplated that such a series may comprise up to about 60 or so process compartments, such as up to about 20 or so process compartments, for example.

As described previously, while one such pump compartment is contemplated as being sufficient for providing approximate gas isolation, multiple such compartments may be used. When one or more such pump compartment(s) are employed, it is contemplated that the number of such pump compartments employed to provide approximate gas isolation will be less than the number of pump compartments otherwise sufficient for providing such approximate gas isolation, or the overall length of such pump compartments or the overall pathway length employed to provide approximate gas isolation will be less than the overall length of pump compartments or overall pathway length otherwise sufficient for providing such approximate gas isolation. Merely by way of example, where two or three or four, etc., pump compartments of a certain pump compartment length may have been employed or needed to provide acceptable gas isolation between coating compartments, it is contemplated that fewer than two or three or four, etc., isolation pump compartments, respectively, such as those described above in relation to FIGS. 6-8, of the same pump compartment length, may be used instead. Further merely by way of example, where two or more pump compartments of an overall or collective pump compartment length or pathway length, may have been employed or needed to provide acceptable gas isolation between coating compartments, it is contemplated that one or more isolation pump compartments, such as those described above in relation to FIGS. 6-8, of a lesser overall or collective pump compartment length or pathway length may be used instead. This may be quite advantageous in terms of reductions in cost, space, and the like, as previously described.

According to an embodiment, the pathway length of a pump compartment or an overall or collective pathway length of multiple pump compartments is less than two times the length of a process compartment that flanks the pump compartment, or less than two times the average length of two process compartments that flank the pump compartment. Merely by way of example, such a pathway length or collective pathway length may be greater than or equal to about the length of a process compartment that flanks the pump compartment, or about the average length of two process compartments that flank the pump compartment. Further merely by way of example, it is contemplated that such a pathway length or collective pathway length may be greater than or equal to about 600 millimeters and less than or equal to about 2010 millimeters. Still further merely by way of example, it is contemplated that such a pathway length or collective pathway length may be from about 750 millimeters or about 850 millimeters and to about 900 millimeters or about 1000 millimeters, for example.

According to an embodiment, gas may be pumped from an apparatus for coating a substrate passing therethrough by providing an apparatus as described or contemplated herein, and pumping gas from the pathway and each of the process compartments that flank the pump compartment via the pumps of the apparatus in association with a substrate coating process. According to this method, it is contemplated that an appropriate level of gas isolation may be achieved, as previously described herein.

In order to evaluate an apparatus that comprises a pump compartment as described or contemplated herein, an evaluation of the gas isolation achieved between two coat or process compartments that flank the pump compartment may be undertaken. Merely by way of example, such an evaluation might involve creating an appropriate vacuum condition in the two coat compartments, such as a base pressure of about 8×10⁻⁶ Torr, for example, providing a process gas to one of the coat compartments (“Compartment 1”) to establish a process pressure, such as a process pressure of about 3×10⁻³ Torr, for example, running the coat process which comprises operating the pumps associated with the pump compartment, and measuring the pressure of the process gas in the other of the coat compartments (“Compartment 2”). Such an evaluation might involve the foregoing process with the exception that the process gas is provided to Compartment 2 and measured in Compartment 1. From these measurements, a gas isolation ratio, as previously described, might be determined, wherein success might be determined relative to gas isolation ratios previously described herein, or that appropriate to a given process. By way of example, it is contemplated that gas isolation levels achieved using an apparatus described or contemplated herein will be approximately the same or better than those achieved using a modular coater, such as that described in connection with FIG. 4 or FIG. 5.

Either or both of the aforementioned evaluations might be run without a substrate and/or with a substrate, such as a glass substrate. When the evaluation is run with a substrate present, the gas isolation ratio would be expected to be higher, such as about 20% higher, for example, relative to the same evaluation that is run in the absence of a substrate, as the presence of the glass would be expected to impede the flow of gas from one coat compartment to the other. Such an increase, or one appropriate to a given process or apparatus, would indicate a successful process or apparatus. A similar evaluation, or similar evaluations, might be conducted using a number of substrates passing through the coat compartments, wherein the substrates moving along the substrate pass line are separated by a gap, such as a gap of about two to three inches. It would be expected that the gap would carry some gas from one coat compartment to the other. When such an evaluation is conducted, it would be expected that a reduction in the gas isolation ratio of about 2% or less, for example, relative to a result achieved when the substrates are not separated by a gap, would result. Such a reduction, or one appropriate to a given process or apparatus, would indicate a successful process or apparatus.

It is contemplated that it may be possible to optimize the performance, efficiency, and/or costs associated with an apparatus described herein by evaluating results obtained using different combinations of pumps, such as diffusion, turbomolecular, cryopumps, and/or other high vacuum pumps, in connection with the isolation pump compartment or compartments. Such optimization might entail taking into consideration pump capacity or speed, pump footprint, any pump downsides, such as possible oil or other contamination, possible backstreaming of gas at process pressure (although same may not be problematic in an isolation pump compartment given the pressure regime in such a compartment), or regeneration issues associated with cryopumps, for example, any pump upsides, such as relative lack of such contamination or relative lack of such backstreaming, for example, and/or the like. Such optimization might further entail arriving at an appropriate balance of these and/or other relevant factors. For example, it may be that an apparatus cannot accommodate diffusion pumps given the relatively large footprint of such pumps, such that a sacrifice as to pump capacity and as to cost must be accepted or accommodated in some way. Further by way of example, it may be that an apparatus is designed to use fewer turbomolecular pumps given the relatively high cost of such pumps, such that a sacrifice as to pump capacity must be accepted or accommodated in some way. Still further by way of example, it may be that some turbomolecular pumps may be replaced by diffusion pumps, although the possibility of oil or other contamination, the relatively high power requirement, and the relatively large footprint associated with diffusion pumps must be accepted or accommodated in some way.

Optimization of a coat process or apparatus might entail configuring the apparatus with various pumps, such as any of the pumps described herein, for example, running a coat process, as previously described herein, and evaluating the gas isolation ratios that result. A successful optimization might involve finding an acceptable balance between the gas isolation ratio results and other factors, such as those described or contemplated herein, for example. Merely by way of example, it is contemplated that anywhere from about two to about three or four turbomolecular pumps might be successfully employed in place of a diffusion pump in a coat process or apparatus described or contemplated herein (with a lower number being desirable in view of the relatively high cost of turbomolecular pumps), provided the gas isolation results are appropriate to the process.

Optimization of a coat process or apparatus might entail a consideration of a user's proposed process or operational parameters, such as gas flow and pressure, for example, and associated calculations, such as calculations based on a selected apparatus or process design, for example. Optimization may involve design and development testing and/or field testing. Measurements made in connection with optimization may involve varying parameters, such as gas flow(s) in a selected pumping configuration, or use of selected gas flow(s) with various pumping configurations, for example. Optimization may involve matching or exceeding gas isolation ratios associated with existing systems or meeting or exceeding gas isolation ratios associated with the desires or needs of a user.

An apparatus for coating a substrate passing therethrough is provided. An apparatus for pumping gas associated with a substrate coating process, such as such an apparatus that may be used in connection with a substrate coating apparatus, is also provided. Such an apparatus generally comprises a pump compartment adapted for operable communication with a process compartment adjacent a first side of the pump compartment and another process compartment adjacent a second side of the pump compartment, as shown and described in relation to FIGS. 6-8, for example. The pump compartment comprises a pathway of a pathway length for passage of a substrate through the pump compartment. The pathway length is less than two times the length of either of the adjacent process compartments or the average of the lengths of the two adjacent process compartments. The apparatus also comprises high vacuum pumps that are operably associated with the pump compartment, as shown and described in relation to FIGS. 6-8, for example. The high vacuum pumps are sufficient for approximately isolating a gas associated with one of the adjacent process compartments and a gas associated with the other of the adjacent process compartments relative to one another in association with the substrate coating process. An associated method that comprises providing such an apparatus for pumping gas associated with a substrate coating process and pumping gas from the pathway and the two adjacent process compartments via the pumps in association with the substrate coating process is also provided.

As described herein, a coating system may comprise a single pump compartment sufficient to provide an acceptable level of gas isolation, where desirable or needed, between process or coat compartments. It is contemplated that when used in a coater, such a single pump compartment may correspond to a gas isolation ratio of more than about 20 to one, such as up to about 35 to one, for example. Use of a single pump compartment in the manner described herein may be advantageous in terms of reductions in equipment costs, coater footprint, configuration time and effort, operational time and effort, and coater complexity, and/or the like, and particularly advantageous in the context of large, multi-module coaters, such as those employed to coat a substrate with five or more layers of material, such as six to eight layers of material, for example, which have heretofore employed or required a significant number of gas isolation compartments. It is contemplated that a variety of multi-module coaters that comprise a configuration of three compartments or bays, in which a single pump compartment is flanked by two coat compartments, such as those described herein, may be useful.

Various modifications, processes, as well as numerous structures that may be applicable herein will be apparent. Various aspects, features or embodiments may have been explained or described in relation to understandings, beliefs, theories, underlying assumptions, and/or working or prophetic examples, although it will be understood that any particular understanding, belief, theory, underlying assumption, and/or working or prophetic example is not limiting. Although the various aspects and features may have been described with respect to various embodiments and specific examples herein, it will be understood that any of same is not limiting with respect to the full scope of the appended claims or other claims that may be associated with this application.

1. An apparatus for coating a substrate passing therethrough, comprising:
a first process compartment sufficient for passage of the substrate therethrough via a first path of a first length extending from an entrance to an exit of the first process compartment and for coating the substrate via a first gas;
a second process compartment sufficient for passage of the substrate therethrough via a second path of a second length extending from an entrance to an exit of the second process compartment and for coating the substrate via a second gas, the first gas and the second gas being the same or different; and
a pump compartment disposed between the first process compartment and the second process compartment, the pump compartment sufficient for passage of a substrate therethrough via a pathway of a pathway length extending from an entrance to an exit of the pump compartment, the pathway in operable communication with the first path and the second path;
the pump compartment in operable communication with the first process compartment, the second process compartment, and the pathway for pumping gas therefrom via pumps;
the pump compartment sufficient for approximately isolating the first gas and the second gas relative to one another in association with a substrate coating process when the pathway length is less than two times the first length, the second length, or the average of the first length and the second length.

2. The apparatus of claim 1 sufficient to provide a ratio of a pressure of the first gas in the first process compartment and a pressure of the first gas in the second process compartment of up to about 35 to 1 in association with the substrate coating process.

3. The apparatus of claim 1 sufficient to provide a ratio of a pressure of the second gas in the second process compartment and a pressure of the second gas in the first process compartment of up to about 35 to 1 in association with the substrate coating process.

4. The apparatus of any one of claim 2 and claim 3 sufficient to provide the ratio of greater than or equal to about 20 to 1 in association with the substrate coating process.

5. The apparatus of claim 1, further comprising at least one further first process compartment adjacent the first process compartment and/or at least one further second process compartment adjacent the second process compartment.

6. The apparatus of claim 5, wherein a number of the first process compartment and the at least one further first process compartment or the second process compartment and the at least one further second process compartment is from about 20 to about 40 per pump compartment.

7. The apparatus any one of claim 1 and claim 5, further comprising at least one further pump compartment adjacent the pump compartment, wherein a number of the pump compartment and the at least one further pump compartment is less than a number of pump compartments otherwise sufficient for such approximately isolating the first gas and the second process gas relative to one another in association with the substrate coating process.

8. The apparatus of claim 1, wherein the pumps are selected from a diffusion pump, a turbomolecular pump, a cryogenic pump, any other high vacuum pump, and/or any combination thereof.

9. The apparatus of claim 1, wherein the pumps comprise at least one diffusion pump for pumping gas from the pathway and at least one pump that is other than a diffusion pump for pumping gas from at least one of the first process compartment and the second process compartment.

10. The apparatus of claim 1, wherein the pumps comprise at least one diffusion pump for pumping gas from the pathway and at least one turbomolecular pump for pumping gas from at least one of the first process compartment and the second process compartment.

11. The apparatus of claim 1, wherein the pumps comprise at least one end pump that is in operable communication with the pump compartment via an end of the pump compartment.

12. The apparatus of claim 11, wherein said at least one end pump comprises a pump for pumping gas from the pathway.

13. The apparatus of claim 11, wherein said at least one end pump comprises a pump selected from a diffusion pump, a turbomolecular pump, a cryopump, any other high vacuum pump, and/or any combination thereof.

14. The apparatus of claim 1, wherein the pumps comprise at least one top pump that is in operable communication with the pump compartment via a top of the pump compartment.

15. The apparatus of claim 14, wherein said at least one top pump comprises a pump for pumping gas from the first process compartment or the second process compartment.

16. The apparatus of claim 14, wherein said at least one top pump comprises at least two top pumps.

17. The apparatus of claim 14, wherein each pump of the at least two top pumps is independently selected from a diffusion pump, a turbomolecular pump, any other high vacuum pump, and/or any combination thereof.

18. The apparatus of claim 1, wherein the pathway length is less than a pathway length of a pumping compartment otherwise sufficient for such approximately isolating the first gas and the second gas relative to one another in association with the substrate coating process.

19. The apparatus of claim 1, wherein the pathway length is less than two times the first length or the second length or less than two times the average of the first length and the second length.

20. The apparatus of claim 19, wherein the pathway length is greater than or equal to about the first length or about the second length or about the average of the first length and the second length.

21. The apparatus of claim 1, wherein the pathway length is from about 600 millimeters to about 2010 millimeters.

22. The apparatus of claim 1, wherein the pathway length is from about 750 millimeters to about 1000 millimeters.

23. The apparatus of claim 1, further comprising at least one baffle separating an area of the pump compartment associated with pumping gas from the first process compartment and another area of the pump compartment associated with pumping gas from the second process compartment.

24. The apparatus of claim 1, further comprising at least one baffle separating an area of the pump compartment associated with pumping gas from the pathway and another area of the pump compartment associated with the pumping of gas from the first process compartment and/or the second process compartment.

25. The apparatus of claim 1, wherein pumps comprise at least one diffusion pump in operable communication with the pump compartment via an end of the pump compartment for pumping gas from the pathway, at least one turbomolecular pump in operable communication with another end of the pump compartment for pumping gas from the pathway, and at least one turbomolecular pump in operable communication with the pump compartment via a top of the pump compartment for pumping gas from the first process compartment and the second process compartment.

26. The apparatus of claim 1, wherein said pumps comprise turbomolecular pumps in operable communication with the pump compartment via a top of the pump compartment for pumping gas from the pathway, the first process compartment, and the second process compartment.

27. A method of pumping gas from an apparatus for coating a substrate passing therethrough, comprising:
providing the apparatus of claim 1; and
pumping gas from the pathway, the first process compartment, and the second process compartment via the pumps in association with the substrate coating process.

28. The method of claim 27, wherein the pumping is sufficient for approximately isolating the first gas and the second gas relative to one another in association with a substrate coating process.

29. An apparatus for pumping gas associated with a substrate coating process, comprising:
a pump compartment adapted for operable communication with a first process compartment adjacent a first side of the pump compartment and of a first length and a second process compartment adjacent a second side of the pump compartment and of a second length, the pump compartment having a pathway of a pathway length for passage of a substrate through the pump compartment, the pathway length being less than two times the first length, the second length, or an average of the first length and the second length; and
high vacuum pumps operably associated with the pump compartment, the high vacuum pumps sufficient for approximately isolating a first gas associated with the first process compartment and a second gas associated with the second process compartment relative to one another in association with the substrate coating process.

30. A method of pumping gas associated with a substrate coating process, comprising:
providing the apparatus of claim 29; and
pumping gas from the pathway, the first process compartment, and the second process compartment via the pumps in association with the substrate coating process.
